(19) United States
(12) Patent Application Publication
(10) Pub. No.: US 2007/0007968 A1
(43) Pub. Date: Jan. 11, 2007

(54) Power monitoring system including a wirelessly communicating electrical power transducer

(76) Inventors: William M. Mauney JR., McMurray, PA (US); Madhav D. Manjrekar, Cary, NC (US)

Correspondence Address: MARTIN J. MORAN, ESQ.;Eaton Electrical, Inc.,, Technology & Quality Center, 170 Industry Drive, RIDX Park West, Pittsburgh, PA, 15275-1032, US

(21) Appl. No.: 11/177,687

(22) Filed: Jul. 8, 2005

(51) Int. Cl. G01R 31/04

(52) U.S. Cl. 324/538

(57) ABSTRACT

A system for monitoring an electrical power system includes one or more transducer units, each of which has a current measuring device and a voltage measuring device coupled to a respective one of the phase conductors of the power system, and a transducer wireless communications device. The transducer wireless communications device of each transducer unit transmits the measured current data and voltage data to a base unit. The base unit generates one or more electrical parameters relating to the power system using the received current data and voltage data. Also, a method of monitoring a power system including generating current and voltage data for each phase conductor at a first location, wirelessly transmitting the current and voltage data to a second location, and generating at the second location electrical parameters relating to the power system using the current and voltage data for each phase conductor.

### BACKGROUND OF THE INVENTION

1. Field of the Invention

The present invention relates to systems for monitoring an electrical power system, and in particular to power monitoring systems that utilize one or more wirelessly communicating electrical power transducers.

2. Background Information

Systems for monitoring alternating current (ac) power systems are well known and typically include discrete analog components which measure ac voltage and current signals from a power system and convert them into direct current (dc) output signals. Such systems also typically include microcomputers for calculating various electrical parameters such as rms currents and voltages, peak currents and voltages, average powers, power factors, alarm limits, over and under voltages, and the like. In addition to monitoring the various electrical parameters of the power system, such monitoring systems also digitally capture portions of the analog waveforms of the power system for harmonic analysis to determine the harmonic content of the waveforms. Examples of such systems are described in commonly owned U.S. Pat. Nos. 5,587,917 and 5,706,204, the disclosures of which are incorporated herein by reference.

Power monitoring systems such as those described above are widely used in many settings and for many purposes. For example, electrical utilities use power monitoring systems for metering purposes to determine the amount of power consumed by its customers. In addition, power monitoring systems are frequently used by power consumers such as businesses and landlords for sub-metering purposes to determine the amount of power consumed by a particular tenant in a building or other location or the amount of power consumed by a particular department or similar unit within a business. Power monitoring systems are also used in process control applications, for example in situations where a motor is powered by a power system, to measure various parameters for preventative maintenance and predictive diagnostics purposes or for implementing load sharing and load shifting schemes. Finally, power monitoring systems are often used for power quality metering to measure parameters such as harmonics, transients, and voltage fluctuations. Power quality metering is often critical in many industrial operating locations, such as pharmaceutical manufacturing facilities, hospitals, data centers or semiconductor fabrication facilities, where it is extremely important to consistently have power of high quality.

In power monitoring, whether it be for single phase, two-phase (also known as split phase) or three-phase ac systems, it is necessary to simultaneously measure the voltage and current of each phase at multiple points of time in the waveform. In existing monitoring systems, this is done with a piece of equipment commonly referred to as a meter box that includes, for each phase, a current measuring device, such as a current transformer or the like, for measuring the current of the phase, and a voltage measuring device, such as a potential transformer, a divider circuit or the like, for measuring the voltage of the phase. Thus, a power monitoring system for a three-phase ac power system will include a meter box having three current measuring devices and three voltage monitoring devices. The current and voltage measuring devices-are connected to an analog-to-digital converter and a processing unit in the meter box which calculates the various monitoring parameters described above.

Existing power monitoring systems present several problems. First, voltage cannot be reliably measured without being physically connected to the conductor, which typically carries voltages on the order of 120-600 VAC or 1,200-40,000 VAC. As a result, the meter boxes that operators must come into contact with are dangerous as they are directly connected to the voltage conductors. In addition. many meter boxes are directly connected to a communications network, such as, for example, Ethernet. The fact that the meter boxes are connected to the voltage conductors present the potential that the voltage could be passed to the communication network when problems arise, which would likely be very harmful to the network and potentially hazardous to the user. Moreover, installation of a metel-box requires that several cables be connected to particular locations. The most common cause of monitoring system failure is errors made in the cable connection process (e.g., phases incorrectly connected).

Thus, there is a need for a power monitoring system with increased safety features that also limits the number of connections that must be made during installation.

### SUMMARY OF THE INVENTION

These needs, and others, are addressed by the present invention which provides a system for monitoring an electrical power system having one or more phase conductors. The system includes one or more transducer units, each of which has a current measuring device operatively coupled to a respective one of the phase conductors, a voltage measuring device electrically coupled to a respective one of the phase conductors, and a transducer wireless communications device. The current measuring device of each transducer unit generates a current signal indicative of a current of the respective phase conductor and the voltage measuring device of each transducer unit generates a voltage signal indicative of a voltage of the respective phase conductor. The transducer wireless communications device of each transducer unit receives current data based on the respective current signal and voltage data based on the respective voltage signal and wirelessly transmits the current data and the voltage data to a base unit. The base unit has a base wireless communications device and a processor electrically coupled to the base wireless communications device. The base wireless communications device receives the current data and the voltage data transmitted by the transducer wireless communications device of each transducer unit, and the processor generates one or more electrical parameters relating to the electrical power system using the received current data and voltage data. The current data and the voltage data associated with each transducer unit may be time synchronized to enable the calculation of line-to-line voltage values and the determination of relative phase information. In addition the voltage data and the current data may be compared to predetermined limits to determine whether an alarm condition exists. If an alarm condition exists, an alarm signal may be wirelessly transmitted to the base unit.

The system may be used to monitor a three-phase power system including a first phase conductor, a second phase conductor and a third phase conductor. In this case, the system includes: (i) a first transducer unit having a first current measuring device operatively coupled to the first phase conductor, a first voltage measuring device electrically coupled to the first phase conductor, and a first transducer wireless communications device, (ii) a second transducer unit having a second current measuring device operatively coupled to the second phase conductor, a second voltage measuring device electrically coupled to the second phase conductor, and a second transducer wireless communications device, and (iii) a third transducer unit having a third current measuring device operatively coupled to the third phase conductor, a third voltage measuring device electrically coupled to the third phase conductor, and a third transducer wireless communications device. The first current measuring device generates a first current signal indicative of a current of the first phase conductor and the first voltage measuring device generates a first voltage signal indicative of a voltage of the first phase conductor, the second current measuring device generates a second current signal indicative of a current of the second phase conductor and the second voltage measuring device generates a second voltage signal indicative of a voltage of the second phase conductor, and the third current measuring device generates a third current signal indicative of a current of the third phase conductor and the third voltage measuring device generates a third voltage signal indicative of a voltage of the third phase conductor. The first transducer wireless communications device receives first current data based on the first current signal and first voltage data based on the first voltage signal, and wirelessly transmits the first current data and the first voltage data, the second transducer wireless communications device receives second current data based on the second current signal and second voltage data based on the second voltage signal and wirelessly transmits the second current data and the second voltage data, and the third transducer wireless communications device receives third current data based on the third current signal and third voltage data based on the third voltage signal and wirelessly transmits the third current data and the third voltage data. The base wireless communications device receives the first, second and third current data and the first, second and third voltage data, and the processor generates the one or more electrical parameters using the first, second and third current data and the first, second and third voltage data.

Each transducer unit may have an analog-to-digital converter for converting the current signal indicative of a current of each phase conductor into the respective current data and for converting the voltage signal indicative of a voltage of each phase conductor into the respective voltage data. In addition, the current measuring device of each transducer unit may comprise a current transformer, and the voltage measuring device of each transducer unit may comprise an RC divider network. The transducer wireless communications devices and the base wireless communications device may each comprise an RF wireless communications device, such as a Bluetooth device or an 802.15 or 802.15.4 device, or, alternatively, an infrared wireless communications device. The processor may also perform waveform harmonic analysis using the received current data and the received voltage data.

The present invention also provides a method of monitoring an electrical power system having one or more phase conductors, including generating current data and voltage data for each of the phase conductors at a first location, wirelessly transmitting the current data and the voltage data for each of the phase conductors to a second location, and generating at the second location one or more electrical parameters relating to the electrical power system using the current data and the voltage data for each of the phase conductors. The current data for each respective phase conductor is indicative of a current of the respective phase conductor and the voltage data for each respective phase conductor is indicative of a voltage of the respective phase conductor.

The method may be used to monitor a three-phase power system having a first phase conductor, a second phase conductor and a third phase conductor, wherein the step of generating current data and voltage data comprises generating first current data indicative of a current of the first phase conductor and first voltage data indicative of a voltage of the first phase conductor, second current data indicative of a current of the second phase conductor and second voltage data indicative of the voltage of the second phase conductor, and third current data indicative of a current of the third phase conductor and third voltage data indicative of a voltage of the third phase conductor. In this case, the step of wirelessly transmitting comprises wirelessly transmitting the first, second and third current data and the first, second and third voltage data to the second location, and the step of generating one or more electrical parameters comprises generating the one or more electrical parameters using the first, second and third current data and the first, second and third voltage data.

Moreover, the step of wirelessly transmitting may utilize radio frequency waves or infrared light. In addition, waveform harmonic analysis may be performed at the second location using the current data and voltage data that is transmitted to the second location.

### BRIEF DESCRIPTION OF THE DRAWINGS

A full understanding of the invention can be gained from the following description of the preferred embodiments when read in conjunction with the accompanying drawings in which:

FIG. 1 is a block diagram of a system for monitoring an electrical power system according to the present invention;

FIG. 2 is a block diagram of a transducer unit forming a part of the system of FIG. 1; and

FIG. 3 is a block diagram of a base unit forming a part of the system of FIG. 1.

### DESCRIPTION OF THE PREFERRED EMBODIMENTS

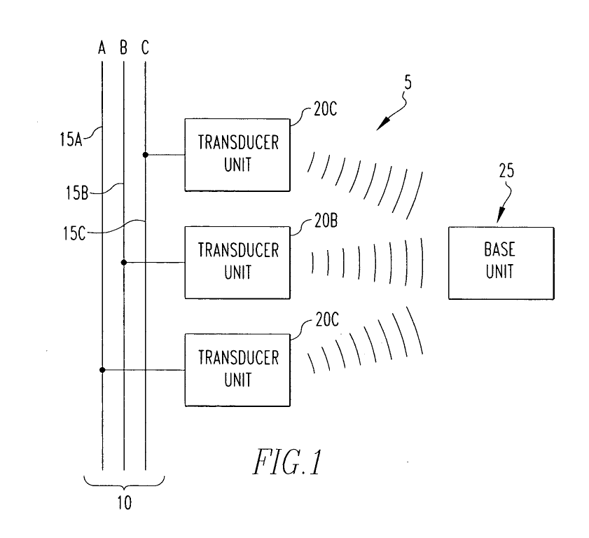

Referring to FIG. 1, monitoring system 5 is used to monitor and analyze electrical power system 10. Electrical power system 10 includes three phase conductors 15A, 15B and 15C. Although not shown, the electrical power system 10 may include one or both of a ground conductor and a neutral conductor. Although a three-phase power system is shown, the invention is applicable to power systems having one or more phase conductors. As seen in FIG. 1, monitoring system 5 includes three transducers units 20A, 20B, 20C. Each transducer unit 20A, 20B, 20C is operatively coupled, as described below, to a respective phase conductor 15A, 15B, 15C, and may be located in close proximity to or remote from one another. Each transducer unit 20A, 20B, 20C measures the current and voltage of the respective phase conductor 15A, 15B, 15C to which it is coupled. Monitoring system 5 further includes base unit 25, preferably located remotely from each transducer unit 20A, 20B, 20C. The data that is measured by each transducer unit 20A, 20B, 20C is transferred wirelessly to base unit 25 as described in more detail below.

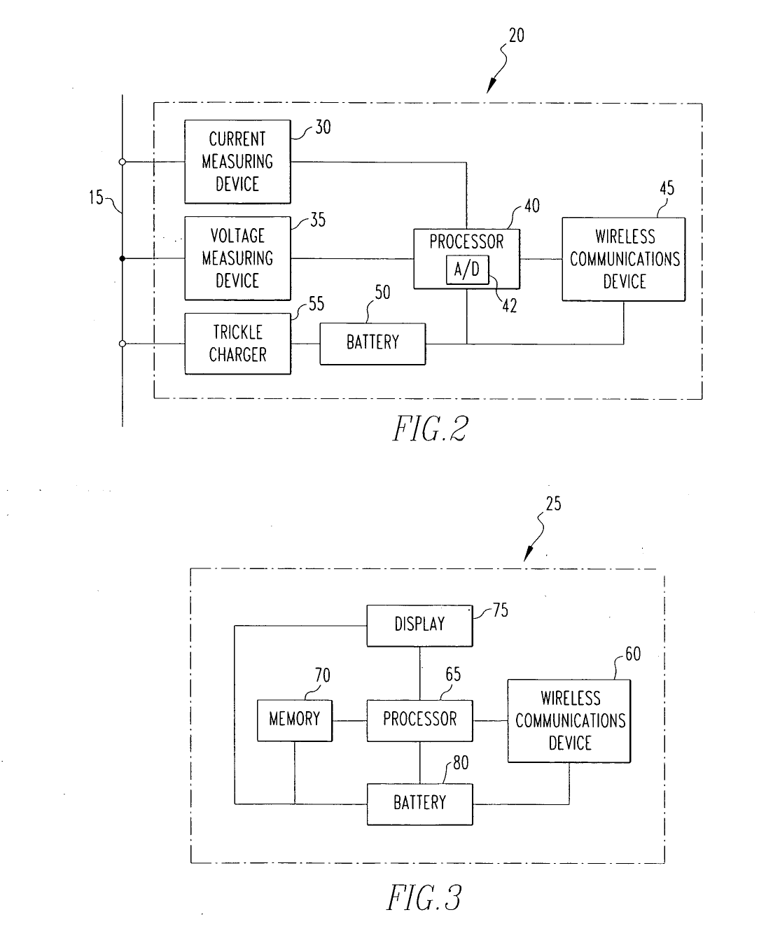

FIG. 2 is a block diagram of a transducer unit 20, which may be any one of transducer units 20A, 20B, 20C. In addition. FIG. 2 shows transducer unit 20 coupled to a phase conductor 15, which may be any one of phase conductors 15A, 15B, 15C. Transducer unit 20 includes current measuring device 30 that is operatively coupled to phase conductor 15 for measuring the current of phase conductor 15. Current measuring device 20 may be any suitable known current measuring device, including, without limitation, a current transformer, a Rogowski current measuring device, a Hall effect device, and a split-core low grade iron-core current sensing device. Transducer unit 20 also includes voltage measuring device 35 that is electrically connected to phase conductor 15 for measuring the voltage of phase conductor 15. Voltage measuring device 35 may be any type of suitable known voltage measuring device, including, without limitation, a potential transformer or an RC divider circuit.

As seen in FIG. 2, current measuring device 30 and voltage measuring device 35 are each electrically connected to processor 40, which may be any type of suitable known processing unit such as a microprocessor. The current related signal generated by current monitoring device 30 and the voltage related signal generated by voltage monitoring device 35, each of which are preferably individual samples at various points in time, are each sent to processor 40. Processor 40 includes an analog-to-digital converter 42 that converts the analog signals generated by current measuring device 30 and voltage measuring device 35 into digital representations thereof. Alternatively, as will be appreciated, the analog-to-digital converter may be a discrete component separate from and connected to processor 40.

Processor 40 is electrically connected to wireless communications device 45. Wireless communications device 45 may be any type of device capable of wirelessly transmitting data, such as wireless transmitter or wireless transceiver. In addition, wireless communications device 45 may transmit data wirelessly in a number of different ways, such as using radio frequency waves according to, for example, the Bluetooth protocol, or using infrared light. Wireless communications device 45 receives the digital signals generated by processor 40 from the signals received from current measuring device 30 and voltage measuring device 35 and transmits them wirelessly to base unit 25.

Transducer unit 20 also includes battery 50 for providing power to each of the components thereof Battery 50 is connected to trickle charger 55, which in turn is electrically coupled to phase conductor 15. Trickle charger 55 is a known parasitic power charger that draws power from phase conductor 15 and uses it to charge battery 50. Alternatively, an iron-core current transformer may be used to parasitically draw power from the phase conductor 15. Such a current transformer may be the same device that functions as current measuring device 30, or a different device. Other methods for providing power to each of the components of transducer unit 20, such as an ac supply, may also be used.

FIG. 3 is a block diagram of base unit 25. Base unit 25 includes wireless communications device 60, similar to wireless communications device 45, that is able to transmit and receive data wirelessly. Wireless communications device 60 receives the data that is transmitted by wireless communications device 45, and in particular, referring again to FIG. 1, from the wireless communications device 45 of each transducer unit 20A, 20B, 20C in system 5. Base unit 25 further includes processor 65, which may be any type of suitable processing unit such as a microprocessor, that is electrically connected to wireless communications device 60. The current and voltage related data received by wireless communications device 60 is transmitted to processor 65. Processor 65 is adapted to process and analyze the received data to calculate and generate, by known methods, various electrical parameters for electric power system 10 including, without limitation, rms currents and voltages, peak currents and voltages, average powers and power factors, alarm limits, and over and under voltage conditions for each phase conductor 15 A, 15B, 15C. In addition, processor 65 is adapted to perform, using known methods, harmonic analysis of the waveforms of power system 10 based on the received data. As seen in FIG. 3, base unit 25 also includes memory 70, such as RAM or the like, for storing the data received by wireless communications device 60 and/or the data generated by processor 65 as described above, and display 75, such as an LCD, for displaying information relating to such data to an operator. Power for the various components of base unit 25 is provided by battery 80 which may, as in the case of battery 50, be connected to a trickle charger (not shown). Other methods for providing power to each of the components of base unit 25, such as an ac supply, may also be used. 04-In an alternative embodiment, processor 40 of transducer unit 20 may be adapted to calculate and generate, using known methods, certain values and/or parameters based on the signals (“raw data”) received from current measuring device 30 and voltage measuring device 35 such as current voltage phase displacement, power factor, harmonic spectra, instantaneous line-to-reference voltage, instantaneous current, RMS line-to-reference voltage, RMS current, average line-to-reference voltage, average current peak line-to-reference voltage, peak current, instantaneous power, RMS power, instantaneous apparent power (kVA), RMS apparent power (kVA), instantaneous reactive power (kVAr), RMS reactive power (kVAr), current THD, voltage THD, and transient event counters (i.e., sag/swell, under/over voltage, voltage transients, power loss, etc.). Such values and/or parameters may be wirelessly transmitted, along with the raw data signals, to base unit 25 for further processing and/or display. In particular, such values and/or parameters may be used to calculate various parameters at base unit 25, such as instantaneous line-to-line voltage, RMS line-to-line voltage, average line-to-line voltage, peak line-to-line voltage, energy readings (including kWh, kVAh, kVArh in all permutations of individual transducers summations for the system and averages for the system), demand readings, i.e., energy readings averaged over a defined time period (e.g., kW demand, kVA demand, kVAr demand), ITIC curve compliance levels, flicker standard compliance measurement, coincident demand levels, peak demand, trend data, and power factor/demand reading pair (for utility penalty billing applications). In addition, the processor 40 may be adapted to compare raw data or values calculated from the raw data (e.g., RMS values) to programmed limits (such as for over voltage or under voltage conditions) and to send alarms to the base unit 25 when the limits are exceeded.

According to a further aspect of the present invention, the measurements made by two or more transducer units 20 may be time synchronized to allow the streams of sampled raw current and voltage data to be time stamped to a relatively high degree of accuracy. This, in turn, would allow the base unit 25 to calculate accurate line-to-line voltage values and to determine relative phase information (e.g., rotation and phase angle). Time synchronization may be accomplished in a number of ways. For example, a plurality of transducer units 20 may be placed into a single housing, and a single-wire communication system may be used to transmit time synchronization information among the transducers 20, and in particular, their processors 40. As will be appreciated, in such a configuration, one transducer unit 20 (the master will maintain a base time that is transmitted to the other transducer units 20 for time stamping purposes. Alternatively, each of a plurality of time synchronized transducer units 20 may be provided with a secondary wireless receiver for receiving time synchronization information from the base unit 25 (in this case, the base unit 25 maintains the base time used for time stamping). In yet another alternative, a plurality of time synchronized transducer units 20 (e.g., transducer units 20 that are measuring different phases of the same load) may be connected in a daisy-chain configuration (e.g., in separate housings) by a single wire pair to allow time synchronization information to be shared among the various transducer units 20. This technique would require that the transducer units 20 be selectively configurable as a master or slave such that one can be designated the master (maintains the base time) and the others the slaves. All of the described examples allow for relative time synchronization among the transducer units 20. Only the configuration where the base unit 25 maintains the time, however, may be used for absolute time synchronization, which could be required for certain multi-point power system monitoring applications (e.g., sequence-of-events recording, protection coordination, or billing applications).

Thus, monitoring system 5 avoids the safety problems (presented both to humans and associated networks) presented by prior art monitoring systems by eliminating the direct, wired connection between the voltage measuring components and the processing and/or display elements that operators must come into contact with on a regular basis. In addition, because each transducer unit 20 of monitoring system 5 is physically connected to only a single phase conductor without the need for further, extensive cabling, the installation errors often encountered by prior art monitoring systems are avoided.

While specific embodiments of the invention have been described in detail, it will be appreciated by those skilled in the art of various modifications and alternatives to those details could be developed in light of the overall teachings of the disclosure. Accordingly, the particular arrangements disclosed are meant to be illustrative only and not limiting as to the scope of the invention which is to be given the full breadth of the claims appended and any and all equivalents thereof.

What is claimed is:

1. A system for monitoring an electrical power system having one or more phase conductors, comprising:
one or more transducer units, each of said one or more transducer units having a current measuring device operatively coupled to a respective one of said one or more phase conductors, a voltage measuring device electrically coupled to a respective one of said one or more phase conductors, and a transducer wireless communications device, said current measuring device of each of said one or more transducer units generating a current signal indicative of a current of said respective one of said one or more phase conductors and said voltage measuring device of each of said one or more transducer units generating a voltage signal indicative of a voltage of said respective one of said one or more phase conductors, said transducer wireless communications device of each of said one or more transducer units receiving current data based on said current signal indicative of a current of said respective one of said one or more phase conductors and voltage data based on said voltage signal indicative of a voltage of said respective one of said one or more phase conductors and wirelessly transmitting said current data and said voltage data; and
a base unit, said base unit having a base wireless communications device and a processor electrically coupled to said base wireless communications device, said base wireless communications device receiving said current data and said voltage data transmitted by said transducer wireless communications device of each of said one or more transducer units, said processor generating one or more electrical parameters relating to said electrical power system using said received current data and said received voltage data.

2. The system according to claim 1, wherein said electrical power system is a three-phase power system, wherein said one or more phase conductors comprise a first phase conductor, a second phase conductor and a third phase conductor, and wherein said one or more transducer units comprise: (i) a first transducer unit having a first current measuring device operatively coupled to said first phase conductor, a first voltage measuring device electrically coupled to said first phase conductor, and a first transducer wireless communications device, (ii) a second transducer unit having a second current measuring device operatively coupled to said second phase conductor, a second voltage measuring device electrically coupled to said second phase conductor, and a second transducer wireless communications device, and (iii) a third transducer unit having a third current measuring device operatively coupled to said third phase conductor, a third voltage measuring device electrically coupled to said third phase conductor, and a third transducer wireless communications device.

3. The system according to claim 2, wherein said first current measuring device generates a first current signal indicative of a current of said first phase conductor and said first voltage measuring device generates a first voltage signal indicative of a voltage of said first phase conductor, said second current measuring device generates a second current signal indicative of a current of said second phase conductor and said second voltage measuring device generates a second voltage signal indicative of a voltage of said second phase conductor, and said third current measuring device generates a third current signal indicative of a current of said third phase conductor and said third voltage measuring device generates a third voltage signal indicative of a voltage of said third phase conductor, wherein said first transducer wireless communications device receives first current data based on said first current signal and first voltage data based on said first voltage signal, and wirelessly transmits said first current data and said first voltage data, said second transducer wireless communications device receives second current data based on said second current signal and second voltage data based on said second voltage signal and wirelessly transmits said second current data and said second voltage data, and said third transducer wireless communications device receives third current data based on said third current signal and third voltage data based on said third voltage signal and wirelessly transmits said third current data and said third voltage data, wherein said base wireless communications device receives said first, second and third current data and said first, second and third voltage data, and wherein said processor generates said one or more electrical parameters using said first, second and third current data and said first, second and third voltage data.

4. The system according to claim 1, wherein each of said one or more transducer units has an analog-to-digital converter for converting said current signal indicative of a current of said respective one of said one or more phase conductors into said current data and for converting said voltage signal indicative of a voltage of said respective one of said one or more phase conductors into said voltage data.

5. The system according to claim 1, wherein said current measuring device of each of said one or more transducer units comprises a current transformer.

6. The system according to claim 1, wherein said voltage measuring device of each of said one or more transducer units comprises an RC divider network.

7. The system according to claim 1, wherein said transducer wireless communications device of each of said one or more transducer units and said base wireless communications device each comprise an radio frequency wireless communications device.

8. The system according to claim 7, wherein said radio frequency wireless communications device is one of a Bluetooth device an 802.15 device and an 802.15.4 device.

9. The system according to claim 1, wherein said transducer wireless communications device of each of said one or more transducer units and said base wireless communications device each comprise an infrared wireless communications device.

10. The system according to claim 1, wherein said processor performs waveform harmonic analysis using said received current data and said received voltage data.

11. The system according to claim 1, wherein said base unit is located remotely from said one or more transducer units.

12. The system according to claim 1, wherein said one or more transducer units comprise at least two transducer units wherein said at least two transducer units are time synchronized such that the current data and the voltage data associated with each of said at least two transducer units is time synchronized.

13. The system according to claim 12, wherein said at least two transducer units are provided within a single housing, said at least two transducer units being in electronic communication with one another in order to share time synchronization information.

14. The system according to claim 12, wherein said at least two transducer units receive time synchronization information from said base unit.

15. The system according to claim 1, wherein each one of said one or more transducer units includes a second processor that receives the current data and the voltage data associated with the one of said one or more transducer units, said second processor being adapted to compare one or both of the received current and voltage data and values calculated from the received current data and voltage data to one or more predetermined limits and to generate one or more alarms based on the comparison.

16. A method of monitoring an electrical power system having one or more phase conductors, comprising:
generating current data and voltage data for each of said one or more phase conductors at a first location, said current data for each respective one of said one or more phase conductors being indicative of a current of said respective of one of said phase conductors and said voltage data for each respective one of said one or more phase conductors being indicative of a voltage of said respective one of said one or more phase conductors;
wirelessly transmitting said current data and said voltage data for each of said one or more phase conductors to a second location: and
generating at said second location one or more electrical parameters relating to said electrical power system using said current data and said voltage data for each of said one or more phase conductors.

17. The method according to claim 16, wherein said electrical power system is a three-phase power system, wherein said one or more phase conductors comprise a first phase conductor, a second phase conductor and a third phase conductor, wherein said step of generating current data and voltage data comprises generating first current data indicative of a current of said first phase conductor and first voltage data indicative of a voltage of said first phase conductor, second current data indicative of a current of said second phase conductor and second voltage data indicative of said voltage of said second phase conductor, and third current data indicative of a current of said third phase conductor and third voltage data indicative of a voltage of said third phase conductor., wherein said step of wirelessly transmitting comprises wirelessly transmitting said first, second and third current data and said first, second and third voltage data to said second location, and wherein said step of generating one or more electrical parameters comprises generating said one or more electrical parameters using said first, second and third current data and said first, second and third voltage data.

18. The method according to claim 16, further comprising employing radio frequency waves to wirelessly transmit said current data and said voltage data.

19. The method according to claim 16, further comprising employing infrared light to wirelessly transmit said current data and said voltage data.

20. The method according to claim 16, further comprising performing at said second location waveform harmonic analysis using said current data and voltage data that is transmitted to said second location.

21. The method according to claim 16, said second location being located remotely from said first location.

22. The method according to claim 16, wherein said one or more phase conductors comprise at least two phase conductors, wherein said current data and said voltage data associated with each of said at least two phase conductors is time synchronized.

23. The method according to claim 16, further comprising, comparing the current data and voltage data for each of said one or more phase conductors to one or more predetermined limits to determine if one or more alarm conditions exists and wirelessly transmitting one or more alarm signals to said second location if it is determined that one or more alarm conditions exists.
